(19) United States
(12) Patent Application Publication
(10) Pub. No.: US 2026/0114295 A1
(43) Pub. Date: Apr. 23, 2026

(54) SEMICONDUCTOR DEVICE AND METHOD OF MANUFACTURING THE SAME

(71) Applicant: Renesas Electronics Corporation, Tokyo (JP)

(72) Inventors: Yasutaka NAKASHIBA, Tokyo (JP); Toshiyuki HATA, Tokyo (JP)

(21) Appl. No.: 19/304,905

(22) Filed: Aug. 20, 2025

(30) Foreign Application Priority Data
Oct. 23, 2024 (JP) 2024-186885

(51) Int. Cl. H01L 23/495; H01L 21/56; H01L 23/00

(52) U.S. Cl. CPC H10W 70/421; H10W 74/01; H10W 90/811; H10W 72/07331

(57) ABSTRACT

A first chip mounting portion and a third chip mounting portion are electrically connected to each other via a first resistor element, and a second chip mounting portion and the third chip mounting portion are electrically connected to each other via a second resistor element.

### CROSS-REFERENCE TO RELATED APPLICATION

The disclosure of Japanese Patent Application No. 2024-186885 filed on Oct. 23, 2024, including the specification, drawings and abstract is incorporated herein by reference in its entirety.

### BACKGROUND

The present disclosure relates to, for example, a semiconductor device and a method of manufacturing the same, and relates to a technique effectively applied to a semiconductor device capable of transmitting signals between different potentials and a method of manufacturing the same.

There are disclosed techniques listed below.
[Patent Document 1] Japanese Unexamined Patent Application Publication No. 2024-072440
[Patent Document 2] Japanese Unexamined Patent Application Publication No. 2023-181601
[Patent Document 3] Japanese Unexamined Patent Application Publication No. 2010-016142

The Patent Documents 1 and 2 describe a technique relating to a transformer enabling contactless signal transmission by use of inductively-coupled lower-layer inductor and upper-layer inductor.

The Patent Document 3 describes a technique relating to a configuration of a transformer enabling division of a breakdown voltage.

### SUMMARY

There are digital isolators each enabling contactless signal transmission from one circuit to the other circuit. In such a digital isolator, it is desirable to improve a withstand voltage to enable the contactless signal transmission between circuits with largely different potentials from each other.

A semiconductor device according to one embodiment includes: a first chip mounting portion to which a first potential is to be supplied; a first semiconductor chip arranged on the first chip mounting portion; a second chip mounting portion to which a second potential is to be supplied, the second potential is higher than the first potential; a second semiconductor chip arranged on the second chip mounting portion; a third chip mounting portion electrically connected to the first chip mounting portion via a first resistor element and electrically connected to the second chip mounting portion via a second resistor element; and an isolator chip arranged on the third chip mounting portion. The isolator chip includes: a lower-layer conductor portion; a first upper-layer conductor portion formed on the lower-layer conductor portion via an insulating layer and electrically connected to the first semiconductor chip; and a second upper-layer conductor portion formed on the lower-layer conductor portion via the insulating layer, spaced apart from the first upper-layer conductor portion, and electrically connected to the second semiconductor chip.

A method of manufacturing a semiconductor device according to one embodiment, includes steps of: (a) preparing a lead frame including a first chip mounting portion, a second chip mounting portion, and a third chip mounting portion; (b) arranging a first semiconductor chip on the first chip mounting portion via a first adhesive material; (c) arranging a second semiconductor chip on the second chip mounting portion via a second adhesive material; (d) arranging an isolator chip on the third chip mounting portion via a third adhesive material; (e) arranging a first chip resistor via a fourth adhesive material so as to straddle the first chip mounting portion and the third chip mounting portion; (f) arranging a second chip resistor via a fifth adhesive material so as to straddle the second chip mounting portion and the third chip mounting portion; and (g) after performing the step (b) to the step (e), preforming a thermal treatment to the lead frame, thereby hardening the first adhesive material, the second adhesive material, the third adhesive material, the fourth adhesive material and the fifth adhesive material.

A method of manufacturing a semiconductor device according to one embodiment includes steps of: (a) preparing a lead frame including a first chip mounting portion, a second chip mounting portion, and a third chip mounting portion; (b) arranging a first semiconductor chip on the first chip mounting portion via a first adhesive material; (c) of arranging a second semiconductor chip on the second chip mounting portion via a second adhesive material; (d) arranging an isolator chip on the third chip mounting portion via a third adhesive material; (e) after performing the step (b) to the step (d), performing a first thermal treatment to the lead frame, thereby hardening the first adhesive material, the second adhesive material and the third adhesive material; (f) after performing the step (e), electrically connecting the first semiconductor chip and the third semiconductor chip to each other via a first bonding wire, and electrically connecting the second semiconductor chip and the third semiconductor chip to each other via a second bonding wire; (g) after performing the step (f), arranging a first chip resistor via a fourth adhesive material so as to straddle the first chip mounting portion and the third chip mounting portion; (h) arranging a second chip resistor via a fifth adhesive material so as to straddle the second chip mounting portion and the third chip mounting portion; and (i) after performing the step (g) and the step (h), performing a second thermal treatment to the lead frame, thereby hardening the fourth adhesive material and the fifth adhesive material.

According to one embodiment, a performance of the semiconductor device can be improved.

### BRIEF DESCRIPTIONS OF THE DRAWINGS

FIG. 1 is a diagram illustrating an exemplary configuration of a drive controller for driving a load circuit.

FIG. 2 is an explanatory diagram illustrating exemplary signal transmission.

FIG. 3 is a diagram illustrating a 3-chip configuration.

FIG. 4 is a diagram for explaining room for improvement.

FIG. 5 is a diagram for explaining a basic concept.

FIG. 6 is a diagram illustrating an exemplary layout configuration of transformers.

FIG. 7 is a diagram illustrating another exemplary layout configuration of transformers.

FIG. 8A is a top view illustrating a mounting configuration of a semiconductor device.

FIG. 8B is a cross-sectional view taken along the line A-A of FIG. 8A.

FIG. 8C is a cross-sectional view taken along the line B-B of FIG. 8A.

FIG. 9 is a diagram illustrating exemplary steps of manufacturing the semiconductor device according to the first embodiment.

FIG. 10 is a diagram illustrating exemplary steps of manufacturing the semiconductor device continued from FIG. 9.

FIG. 11 is a diagram illustrating exemplary steps of manufacturing the semiconductor device continued from FIG. 10.

FIG. 12 is a diagram illustrating exemplary steps of manufacturing the semiconductor device continued from FIG. 11.

FIG. 13 is a diagram illustrating exemplary steps of manufacturing the semiconductor device continued from FIG. 12.

FIG. 14 is a diagram illustrating exemplary steps of manufacturing the semiconductor device continued from FIG. 13.

FIG. 15 is a diagram illustrating another exemplary steps of manufacturing the semiconductor device according to the first embodiment.

FIG. 16 is a diagram illustrating another exemplary steps of manufacturing the semiconductor device continued from FIG. 15.

FIG. 17 is a diagram schematically illustrating a “through-gate molding system.”

FIG. 18 is a diagram illustrating a molding step in the first embodiment.

FIG. 19 is a diagram illustrating the molding step continued from FIG. 18.

FIG. 20 is a diagram illustrating the molding step continued from FIG. 19.

FIG. 21 is a diagram illustrating the molding step continued from FIG. 20.

FIG. 22A is a top view illustrating a mounting configuration of a semiconductor device.

FIG. 22B is a cross-sectional view taken along the line A-A of FIG. 22A.

FIG. 23A is a top view illustrating a mounting configuration of a semiconductor device.

FIG. 23B is a cross-sectional view taken along the line A-A of FIG. 23A.

FIG. 24A is a top view illustrating a mounting configuration of a semiconductor device.

FIG. 24B is a cross-sectional view taken along the line A-A of FIG. 24A.

### DETAILED DESCRIPTION

The same components are denoted by the same reference symbols in principle throughout all the drawings for describing embodiments, and the repetitive description thereof is omitted. Note that even a plan view may be hatched so as to make the drawings easy to see.

The term “digital isolator” is used to broadly include devices enabling contactless signal transmission from one circuit to the other circuit. For example, the digital isolator includes a transformer using magnetic coupling and a capacitor using capacitive coupling. The technical concept of the present disclosure is broadly applicable to the digital isolator including the transformer and the capacitor. The following description will be made in an assumption based on the transformer.

Note that a chip on which the “digital isolator” is formed is referred to as “isolator chip.” A chip on which the “transformer” is formed is referred to as “transformer chip.” Thus, the term “isolator chip” is a term of a broader concept including the “transformer chip”.

### Circuit Configuration

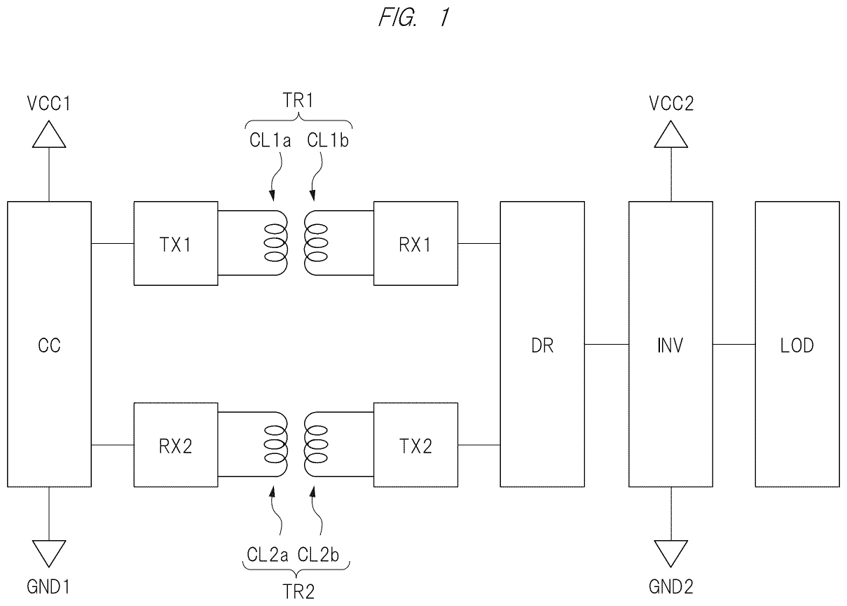

FIG. 1 is a diagram illustrating an exemplary configuration of a drive controller for driving a load circuit such as motor.

As illustrated in FIG. 1, the drive controller includes a control circuit CC, a transmission circuit TX1, a reception circuit RX1, a transmission circuit TX2, a reception circuit RX2, a transformer TR1, a transformer TR2, a drive circuit DR, and an inverter INV.

The transmission circuit TX1 and the reception circuit RX1 are circuits for transmitting a control signal output from the control circuit CC to the drive circuit DR. To the contrary, the transmission circuit TX2 and the reception circuit RX2 are circuits for transmitting a signal output from the drive circuit DR to the control circuit CC.

The control circuit CC is a circuit having a function to control the drive circuit DR. The drive circuit DR is a circuit operating the inverter INV for controlling a load circuit LOD under control of the control circuit CC. The inverter INV is electrically connected to the load circuit LOD.

A power potential VCC1 is to be supplied to the control circuit CC. The control circuit CC is grounded by a ground potential GND1. To the contrary, a power potential VCC2 is supplied to the inverter INV. The inverter INV is grounded by a ground potential GND2. For example, the power potential VCC1 is lower than the power potential VCC2 supplied to the inverter INV. In other words, the power potential VCC2 supplied to the inverter INV is higher than the power potential VCC1.

The transformer TR1 made of inductively- (magnetically-) coupled coils (inductors) CL1a and CL1b is present between the transmission circuit TX1 and the reception circuit RX1. Thereby, a signal can be transmitted from the transmission circuit TX1 to the reception circuit RX1 via the transformer TR1. Consequently, the drive circuit DR can receive the control signal output from the control circuit CC via the transformer TR1.

By the transformer TR1 using the inductive coupling and being electrically isolated, the control signal can be transmitted from the control circuit CC to the drive circuit DR while suppressing electric noise transmission from the control circuit CC to the drive circuit DR. Thus, the malfunction of the drive circuit DR due to electric noise superimposed on the control signal can be suppressed. Thereby, operation reliability of the semiconductor device can be improved.

Each of the coil CL1a and the coil CL1b configuring the transformer TR1 functions as an inductor. The transformer TR1 functions as a magnetic coupling element made of the inductively-coupled coils CL1a and CL1b.

The transformer TR2 made of inductively-coupled coils CL2a and CL2b is present between the transmission circuit TX2 and the reception circuit RX2. Thereby, a signal can be transmitted from the transmission circuit TX2 to the reception circuit RX2 via the transformer TR2. Consequently, the control circuit CC can receive a signal output from the drive circuit DR via the transformer TR2.

By the transformer TR2 using the inductive coupling and being electrically isolated, the signal can be transmitted from the drive circuit DR to the control circuit CC while suppressing electric noise transmission from the drive circuit DR to the control circuit CC. Thus, the malfunction of the control circuit CC due to electric noise superimposed on the signal can be suppressed. Thereby, operation reliability of the semiconductor device can be improved.

The transformer TR1 is made of the coil CL1a and the coil CL1b. The coil CL1a and the coil CL1b are not coupled via a conductor but are magnetically coupled. Thus, when a current flows in the coil CL1a, an induced electromotive force is caused in the coil CL1b in response to the change of the current, and an induced current flows. At this time, the coil CL1a is a primary coil, and the coil CL1b is a secondary coil.

The transformer TR1 uses an electromagnetic induction phenomenon caused between the coil CL1a and the coil CL1b. That is, an induced current caused in the coil CL1b in the transformer TR1 as a result of signal transmission from the transmission circuit TX1 to the coil CL1a in the transformer TR1 to pass a current is sensed by the reception circuit RX1, thereby enabling the reception circuit RX1 to receive a signal corresponding to the control signal output from the transmission circuit TX1.

The transformer TR2 is made of the coil CL2a and the coil CL2b. The coil CL2a and the coil CL2b are not coupled via a conductor but are magnetically coupled. Thus, when a current flows in the coil CL2b, an induced electromotive force is caused in the coil CL2a in response to the change of the current, and an induced current flows.

An induced current caused in the coil CL2a in the transformer TR2 as a result of signal transmission from the transmission circuit TX2 to the coil CL2b in the transformer TR2 to pass a current is sensed by the reception circuit RX2, thereby enabling the reception circuit RX2 to receive a signal corresponding to the control signal output from the transmission circuit TX2.

Signals are transmitted/received between the control circuit CC and the drive circuit DR in the route from the transmission circuit TX1 to the reception circuit RX1 via the transformer TR1 and in the route from the transmission circuit TX2 to the reception circuit RX2 via the transformer TR2.

That is, since the reception circuit RX1 receives a signal transmitted from the transmission circuit TX1 while the reception circuit RX2 receives a signal transmitted from the transmission circuit TX2, the signals can be transmitted/received between the control circuit CC and the drive circuit DR.

The signal transmission from the transmission circuit TX1 to the reception circuit RX1 is performed via the transformer TR1. To the contrary, the signal transmission from the transmission circuit TX2 to the reception circuit RX2 is performed via the transformer TR2. Thereby, the drive circuit DR can drive the inverter INV for operating the load circuit LOD in response to the signal transmitted from the control circuit CC.

The control circuit CC and the drive circuit DR are different from each other in voltage level of reference potential. That is, in the control circuit CC, the reference potential is fixed at the ground potential GND1. To the contrary, the drive circuit DR is electrically connected to the inverter INV as illustrated in FIG. 1.

The inverter INV includes, for example, a high-side insulated gate bipolar transistor (IGBT) and a low-side IGBT. In the inverter INV, the high-side IGBT and the low-side IGBT are controlled to be turned ON/OFF by the drive circuit DR, thereby enabling the inverter INV to control the load circuit LOD.

Specifically, the high-side IGBT can be controlled to be turned ON/OFF by control of the drive circuit DR for a potential applied to a gate electrode of the high-side IGBT. The low-side IGBT can be controlled to be turned ON/OFF by control of the drive circuit DR for a potential applied to a gate electrode of the low-side IGBT.

For example, with reference to the emitter potential (0V) of the low-side IGBT connected to the ground potential GND2, the low-side IGBT can be controlled to be turned ON by applying “emitter potential (0V)+threshold voltage (15 V)” to the gate electrode.

To the contrary, for example, with reference to the emitter potential (0V) of the low-side IGBT connected to the ground potential GND2, the low-side IGBT can be controlled to be turned OFF by applying “emitter potential (0V)” to the gate electrode.

Thus, the low-side IGBT is controlled to be turned ON/OFF, depending on whether the threshold voltage (15 V) with reference to the reference voltage of 0V is applied to the gate electrode.

To the contrary, for example, the high-side IGBT is controlled to be turned ON, depending on whether “reference potential+threshold voltage (15 V)” with reference to the emitter potential of the high-side IGBT as the reference potential is applied to the gate electrode.

However, the emitter potential of the high-side IGBT is not always fixed at the ground potential GND2 as different from the emitter potential of the low-side IGBT. That is, in the inverter INV, the high-side IGBT and the low-side IGBT are connected in series between the power potential VCC2 and the ground potential GND2.

In the inverter INV, the low-side IGBT is controlled to be turned OFF when the high-side IGBT is turned ON, while the low-side IGBT is controlled to be turned ON when the high-side IGBT is turned OFF. Thus, the low-side IGBT is turned ON when the high-side IGBT is turned OFF. Thereby, the emitter potential of the high-side IGBT is brought to the ground potential GND2 by the low-side IGBT turned ON.

To the contrary, since the low-side IGBT is turned OFF when the high-side IGBT is turned ON, the emitter potential of the high-side IGBT is brought to an IGBT bus voltage.

The high-side IGBT is controlled to be turned ON/OFF, depending on whether “reference voltage+threshold voltage (15 V)” with reference to the emitter potential of the high-side IGBT as the reference voltage is applied to the gate electrode. In this regard, the emitter potential of the high-side IGBT differs between when the high-side IGBT is turned ON and when it is turned OFF.

That is, the emitter potential of the high-side IGBT varies from the ground potential GND2 (0V) to the power potential VCC2 (for example, 800V). Thus, in order to turn ON the high-side IGBT, it is necessary to apply “IGBT bus voltage (800V)+threshold voltage (15 V)” with reference to the emitter potential of the high-side IGBT as the reference voltage to the gate electrode.

As described above, the drive circuit DR for controlling the high-side IGBT to be turned ON/OFF needs to recognize the emitter potential of the high-side IGBT. Thus, the drive circuit DR is configured to receive, as an input, the emitter potential of the high-side IGBT. Consequently, the reference potential of 800V is input to the drive circuit DR, and the drive circuit DR controls the high-side IGBT to be turned ON by applying the threshold voltage of 15 V with reference to the reference potential of 800V to the gate electrode of the high-side IGBT. Therefore, the high potential of about 800V is applied to the drive circuit DR.

As described above, the drive controller includes the control circuit CC handling the low potential (several tens of V) and the drive circuit DR handling the high potential (several hundreds of V).

Thus, for the signal transmission between the control circuit CC and the drive circuit DR, signal transmission between different-potential circuits is necessary. In this regard, the signal transmission between the control circuit CC and the drive circuit DR is performed via the transformer TR1 and the transformer TR2, and thus, the signal transmission between the different-potential circuits is enabled.

Since a large potential difference may be caused between the primary coil and the secondary coil in the transformer TR1 and the transformer TR2, the primary coil and the secondary coil which are not coupled via a conductor but are magnetically coupled are used for the signal transmission. Thus, in forming the transformer TR1, it is important to increase a withstand voltage between the coil CL1a and the coil CL1b as much as possible in order to improve the operation reliability of semiconductor device. In forming the transformer TR2, it is important to increase a withstand voltage between the coil CL2a and the coil CL2b as much as possible in order to improve the operation reliability of semiconductor device.

### Exemplary Signal Transmission

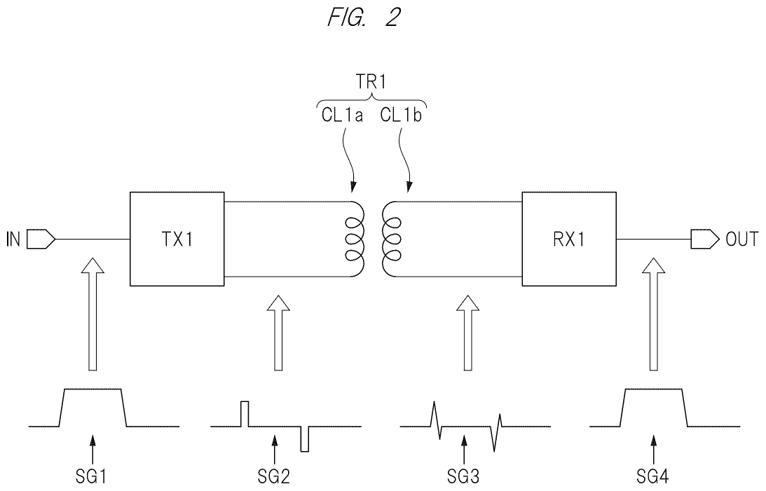

FIG. 2 is an explanatory diagram illustrating exemplary signal transmission.

In FIG. 2, the transmission circuit TX1 extracts an edge of a square signal SG1 which is input to the transmission circuit TX1, generates a signal SG2 with a constant pulse width, and transmits the signal SG2 to the coil CL1a (primary coil) in the transformer TR1. When a current based on the signal SG2 flows in the coil CL1a (primary coil) in the transformer TR1, a signal SG3 corresponding to the current is flown in the coil CL1b (secondary coil) in the transformer TR1 by an induced electromotive force. The signal SG3 is amplified and is further modulated into a square wave by the reception circuit RX1, thereby outputting a square signal SG4 from the reception circuit RX1.

Thereby, the signal SG4 corresponding to the signal SG1 input to the transmission circuit TX1 can be output from the reception circuit RX1. As described above, the signal can be transmitted from the transmission circuit TX1 to the reception circuit RX1. The same goes for the signal transmission from the transmission circuit TX2 to the reception circuit RX2.

### Benefits of 3-Chip Configuration

The transmission/reception circuit in the drive controller can be achieved by, for example, a 2-chip configuration using a first semiconductor chip and a second semiconductor chip. The first semiconductor chip includes the transmission circuit TX1, the transformer TR1, and the reception circuit RX2. To the contrary, the second semiconductor chip includes the reception circuit RX1, the drive circuit DR, the transmission circuit TX2, and the transformer TR2.

However, in the 2-chip configuration, the transformer TR1, the transmission circuit TX1, and the reception circuit RX2 need to be formed on the first semiconductor chip. Thus, a process of manufacturing the first semiconductor chip is complicated. Alternatively, the transformer TR2, the drive circuit DR, the reception circuit RX1, and the transmission circuit TX2 need to be formed on the second semiconductor chip. Thus, a process of manufacturing the second semiconductor chip is complicated. Consequently, the cost of manufacturing the first semiconductor chip and the second semiconductor chip may increase.

Thus, a 3-chip configuration has been studied instead of the 2-chip configuration.

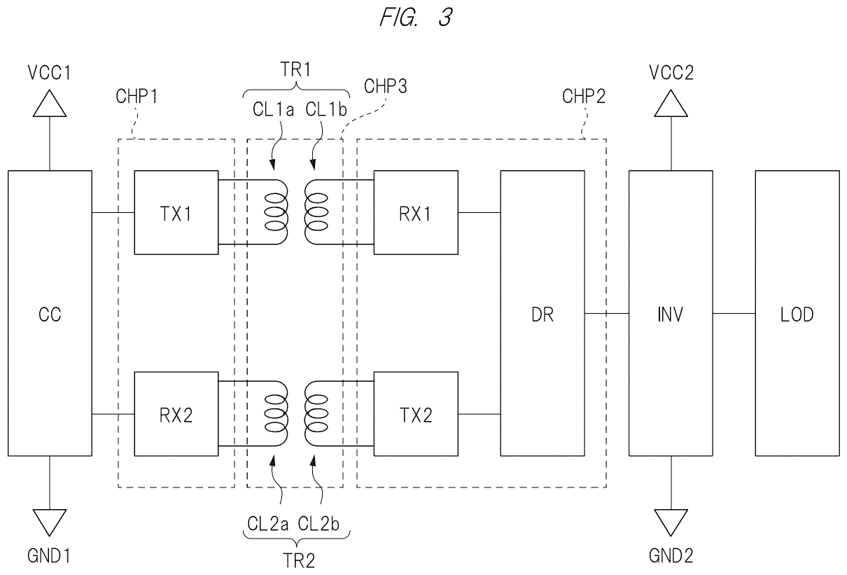

FIG. 3 is a diagram illustrating a 3-chip configuration.

In FIG. 3, a semiconductor chip CHP1 includes the transmission circuit TX1 and the reception circuit RX2. A semiconductor chip CHP2 includes the drive circuit DR, the reception circuit RX1, and the transmission circuit TX2. To the contrary, a semiconductor chip CHP3 includes the transformer TR1 and the transformer TR2.

Thereby, the 3-chip configuration includes the semiconductor chip CHP3 in which only the transformer TR1 and the transformer TR2 are formed. That is, in the 3-chip configuration, the semiconductor chip CHP3 can be used irrespective of the configurations of the semiconductor chip CHP1 and the semiconductor chip CHP2. Thus, the 3-chip configuration can increase variation of the usable semiconductor chip CHP1 and semiconductor chip CHP2. In other words, the versatility of the semiconductor chip CHP3 in which the transformer TR1 and the transformer TR2 are formed can be enhanced.

Further, the semiconductor chip CHP3 in which the transformer TR1 and the transformer TR2 are formed does not include a transistor. Thus, the semiconductor chip CHP3 can be formed only by a wiring step, and, as a result, the manufacturing process can be simplified.

Therefore, the 3-chip configuration can reduce the manufacturing cost.

The semiconductor chip CHP3 including the transformer TR1 and the transformer TR2 may be referred to as “transformer chip” below.

### Study on Improvement

For example, the Patent Documents 1 and 2 cited in the chapter <BACKGROUND> describe the 3-chip configuration including the “transformer chip.”

The “transformer chip” includes a lower-layer inductor arranged in a lower layer in a multi-layered wiring layer and an upper-layer inductor arranged in an upper layer in the multi-layered wiring layer.

In recent years, there is a demand of high withstand voltage in the “transformer chip” in order to improve the performance of the semiconductor device including the “transformer chip”. In order to achieve the high withstand voltage, for example, an increase in a thickness of an interlayer insulating film between the lower-layer inductor and the upper-layer inductor has been studied. This is because the thickened interlayer insulating film increases a distance between the lower-layer and upper-layer inductors facing each other, thereby securing the withstand voltage between the lower-layer inductor and the upper-layer inductor.

However, when the thickened interlayer insulating film is formed on a semiconductor substrate, film stress is caused on the semiconductor substrate by the thickened interlayer insulating film. Consequently, the semiconductor substrate is “warped”.

The “warped” “transformer chip” causes a risk of problems on the subsequent working steps. Thus, the “transformer chip” desirably secures the high withstand voltage without causing the “warpage.”

In this regard, for example, the Patent Document 3 is cited in the chapter <BACKGROUND>. The Patent Document 3 describes a transformer configuration capable of dividing the withstand voltage.

The “transformer chip” described in the Patent Document 3 includes a lower-layer inductor arranged in a lower layer in a multi-layered wiring layer, and first and second upper-layer inductors arranged in an upper layer in the multi-layered wiring layer. The first upper-layer inductor and the second upper-layer inductor are spaced apart from each other. Thereby, a voltage applied to the “transformer chip” is divided into a first voltage applied between the lower-layer inductor and the first upper-layer inductor and a second voltage applied between the lower-layer inductor and the second upper-layer inductor.

Consequently, for example, if the thickness of the interlayer insulating film in the “transformer chip” described in the Patent Document 3 is equal to the thickness of the interlayer insulating film in the “transformer chip” described in each of the Patent Documents 1 and 2, the “transformer chip” described in the Patent Document 3 can secure the withstand voltage double higher than that of the “transformer chip” described in each of the Patent Documents 1 and 2.

In other words, if the withstand voltage of the “transformer chip” described in the Patent Document 3 is equal to the withstand voltage of the “transformer chip” described in each of the Patent Documents 1 and 2, the thickness of the interlayer insulating film in the “transformer chip” described in the Patent Document 3 is only half the thickness of the interlayer insulating film in the “transformer chip” described in each of the Patent Documents 1 and 2.

As described above, the technique described in the Patent Document 3 can secure the higher withstand voltage without increasing the thickness of the interlayer insulating film than that of the technique described in each of the Patent Documents 1 and 2.

However, the present inventors have found that the technique described in the Patent Document 3 has a room for improvement, and thus, the room for improvement will be described below.

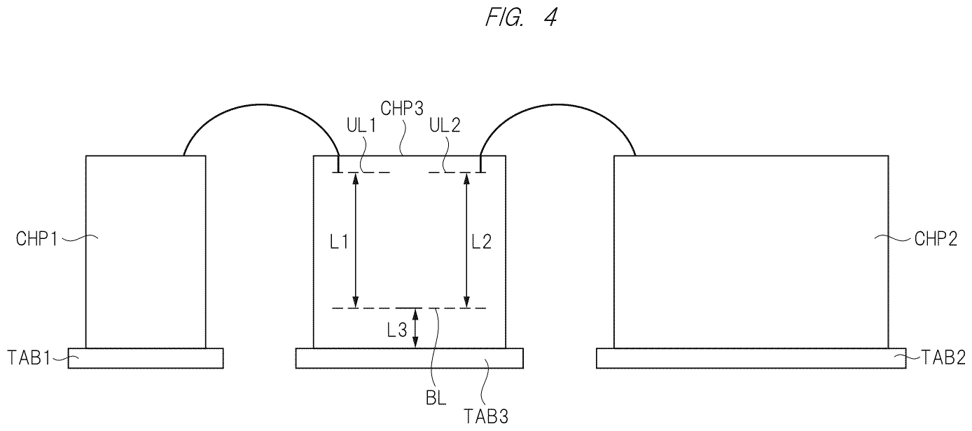

FIG. 4 is a diagram for explaining the room for improvement.

In FIG. 4, the semiconductor device includes a chip mounting portion TAB1, a chip mounting portion TAB2, a chip mounting portion TAB3, the semiconductor chip CHP1, the semiconductor chip CHP2, and the semiconductor chip CHP3 (transformer chip).

The semiconductor chip CHP1 is arranged on the chip mounting portion TAB1. For example, “0V” is supplied to the chip mounting portion TAB1.

The semiconductor chip CHP2 is arranged on the chip mounting portion TAB2. For example, “800V” is supplied to the chip mounting portion TAB2.

The semiconductor chip CHP3 is arranged on the chip mounting portion TAB3. The transformer is formed on the semiconductor chip CHP3.

Specifically, as illustrated in FIG. 4, the semiconductor chip CHP3 includes a lower-layer inductor BL, a first upper-layer inductor UL1, and a second upper-layer inductor UL2. The lower-layer inductor BL, the first upper-layer inductor UL1, and the second upper-layer inductor UL2 are a component of the transformer. The semiconductor chip CHP3 includes a multi-layered wiring layer. The lower-layer inductor BL is arranged in a lower layer in the multi-layered wiring layer. The first upper-layer inductor UL1 is arranged in an upper layer in the multi-layered wiring layer. The second upper-layer inductor UL2 is arranged in the upper layer in the multi-layered wiring layer. The second upper-layer inductor UL2 is arranged in the same wiring layer of the multi-layered wiring layer as the wiring layer where the first upper-layer inductor UL1 is arranged.

For example, as illustrated in FIG. 4, the distance between the lower-layer inductor BL and the first upper-layer inductor UL1 is “L1.” The distance between the lower-layer inductor BL and the second upper-layer inductor UL2 is “L2.” The distance between the lower-layer inductor BL and the chip mounting portion TAB3 is “L3.” The distance “L3” is smaller than each of the distance “L1” and the distance “L2.” The distance “L2” is equal to the distance “L1.”

The first upper-layer inductor UL1 is electrically connected to the semiconductor chip CHP1. The voltage “0V” is supplied to the first upper-layer inductor UL1. The second upper-layer inductor UL2 is electrically connected to the semiconductor chip CHP2. The voltage “800V” is supplied to the second upper-layer inductor UL2. To the contrary, the lower-layer inductor BL is floating.

It is assumed herein that the chip mounting portion TAB3 is floating. In this case, both the chip mounting portion TAB3 and the lower-layer inductor BL are floating. Even if both the chip mounting portion TAB3 and the lower-layer inductor BL are floating, the chip mounting portion TAB3 and the lower-layer inductor BL are capacitively coupled but are floating, and thus, the potential of the lower-layer inductor BL is unstable.

To the contrary, the voltage “0V” is supplied to the first upper-layer inductor UL1, and thus, the floating state is not caused. The voltage “800V” is supplied to the second upper-layer inductor UL2, and the floating state is not caused. The lower-layer inductor BL is capacitively coupled with the first upper-layer inductor UL1, and is capacitively coupled with the second upper-layer inductor UL2. Note that the distances “L1” and “L2” are larger than the distance “L3.”

Therefore, the capacitive coupling between the lower-layer inductor BL and the first upper-layer inductor UL1 is an extremely small capacitive coupling. The capacitive coupling between the lower-layer inductor BL and the second upper-layer inductor UL2 is also an extremely small capacitive coupling. The potential of the lower-layer inductor BL is not stabilized by the extremely small capacitive coupling. Thus, in the viewpoint of the stabilization of the potential of the lower-layer inductor BL, the chip mounting portion TAB3 is not to be floating.

Thus, supply of an intermediate potential (400V) to the chip mounting portion TAB3 is conceivable. In this case, the chip mounting portion TAB3 is not floating. The lower-layer inductor BL is capacitively coupled with the chip mounting portion TAB3. Note that the distance “L3” is smaller than each of the distances “L1” and “L2.” Therefore, the capacitive coupling between the lower-layer inductor BL and the chip mounting portion TAB3 is a larger capacitive coupling than the capacitive coupling between the lower-layer inductor BL and each upper-layer inductor (the first upper-layer inductor UL1 and the second upper-layer inductor UL2). Additionally, a plane area of the chip mounting portion TAB3 is larger than a plane area of the first upper-layer inductor UL1 and a plane area of the second upper-layer inductor UL2. Thus, the capacitive coupling between the lower-layer inductor BL and the chip mounting portion TAB3 is an extremely large capacitive coupling. Consequently, the potential of the lower-layer inductor BL is stabilized. As described above, in order to stabilize the potential of the lower-layer inductor BL, the supply of the intermediate potential (“400V”) to the chip mounting portion TAB3 is desirable. However, for the supply of the intermediate potential (“400V”) to the chip mounting portion TAB3, it is necessary to prepare a power supply circuit for generating the intermediate potential. This case complicates the circuit configuration. Thus, it is desirable to achieve a configuration for the supply of the intermediate potential (“400V”) to the chip mounting portion TAB3 without preparing the power supply circuit for generating the intermediate potential.

### Basic Concept

FIG. 5 is a diagram for explaining a basic concept.

In FIG. 5, the basic concept is to electrically connect the chip mounting portion TAB1 and the chip mounting portion TAB3 via a resistor element R1 and electrically connect the chip mounting portion TAB2 and the chip mounting portion TAB3 via a resistor element R2.

Thereby, a potential (third potential) applied to the chip mounting portion TAB3 is higher than a potential (first potential) applied to the chip mounting portion TAB1 and is lower than a potential (second potential) applied to the chip mounting portion TAB2. For example, when “0V” is supplied to the chip mounting portion TAB1 while “800V” is supplied to the chip mounting portion TAB2, if a resistance value of the resistor element R1 is equal to a resistance value of the resistor element R2, then, the intermediate potential of “400V” is applied to the chip mounting portion TAB3. That is, according to the basic concept, the intermediate potential can be applied to the chip mounting portion TAB3 without preparing the power supply circuit for generating the intermediate potential. In other words, in the basic concept, the intermediate potential is applied to the chip mounting portion TAB3 by arranging the resistor elements between “800V” and “0V”. Thus, the basic concept does not need the power supply circuit for supplying the intermediate potential to the chip mounting portion TAB3. Consequently, the semiconductor device adopting the basic concept can stabilize the potential of the lower-layer inductor BL, without the complicated circuit configuration.

The semiconductor device adopting the basic concept has the following configuration.

The semiconductor device includes: the chip mounting portion TAB1 to which the first potential (0V) is to be supplied; the semiconductor chip CHP1 arranged on the chip mounting portion TAB1; the chip mounting portion TAB2 to which the second potential (800V) is to be supplied, the second potential being higher than the first potential; the semiconductor chip CHP2 arranged on the chip mounting portion TAB2; the chip mounting portion TAB3 electrically connected to the chip mounting portion TAB1 via the resistor element R1 and electrically connected to the chip mounting portion TAB2 via the resistor element R2; and the semiconductor chip CHP3 arranged on the chip mounting portion TAB3.

For example, the resistor element R1 can be made of a chip resistor. The resistor element R2 can be also made of a chip resistor. The resistance value of the resistor element R1 and the resistance value of the resistor element R2 can be appropriately set in, for example, a range of 5 MΩ to 50 MΩ depending on a voltage to be applied to the chip mounting portion TAB3.

The semiconductor chip CHP3 includes: the lower-layer inductor BL; the first upper-layer inductor UL1 formed on the lower-layer inductor BL via an insulating layer and electrically connected to the semiconductor chip CHP1; and the second upper-layer inductor UL2 formed on the lower-layer inductor BL via an insulating layer, being spaced apart from the first upper-layer inductor UL1, and electrically connected to the semiconductor chip CHP2.

Embodiments of the embodied basic concept will be described below.

### First Embodiment

### Layout Configuration of Transformers

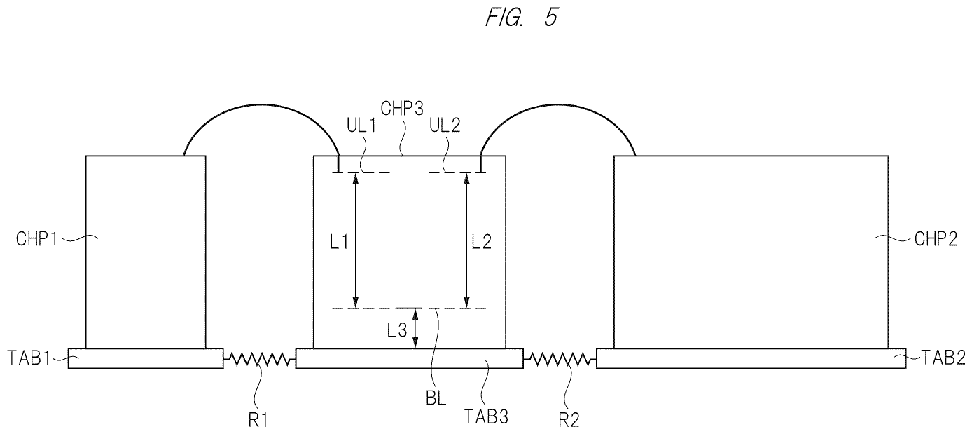

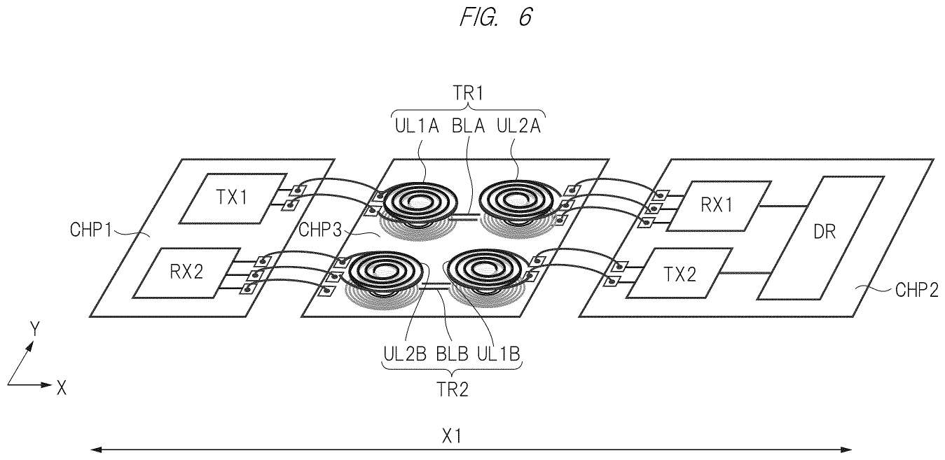

FIG. 6 is a diagram illustrating an exemplary layout configuration of transformers.

In FIG. 6, the semiconductor chip CHP3 is the “transformer chip”. The semiconductor chip CHP3 includes the transformer TR1 and the transformer TR2.

The transformer TR1 includes a lower-layer inductor BLA, a first upper-layer inductor UL1A, and a second upper-layer inductor UL2A.

The first upper-layer inductor UL1A and the second upper-layer inductor UL2A are arranged above the lower-layer inductor BLA. The lower-layer inductor BLA and the first upper-layer inductor UL1A are magnetically coupled. The lower-layer inductor BLA and the second upper-layer inductor UL2A are also magnetically coupled. As illustrated in FIG. 6, the first upper-layer inductor UL1A and the second upper-layer inductor UL2A are arranged side by side in the X direction while being spaced apart from each other.

The arrangement direction in plan view of the semiconductor chip CHP1, the semiconductor chip CHP3 and the semiconductor chip CHP2 is the X direction. Thus, the arrangement direction in plan view of the first upper-layer inductor UL1A and the second upper-layer inductor UL2A is parallel to the arrangement direction in plan view of the semiconductor chip CHP1, the semiconductor chip CHP3 and the semiconductor chip CHP2.

The transformer TR2 includes a lower-layer inductor BLB, a first upper-layer inductor UL1B, and a second upper-layer inductor UL2B.

The first upper-layer inductor UL1B and the second upper-layer inductor UL2B are arranged above the lower-layer inductor BLB. The lower-layer inductor BLB and the first upper-layer inductor UL1B are magnetically coupled. The lower-layer inductor BLB and the second upper-layer inductor UL2B are also magnetically coupled. As illustrated in FIG. 6, the first upper-layer inductor UL1B and the second upper-layer inductor UL2B are arranged side by side in the X direction while being spaced apart from each other.

The arrangement direction in plan view of the semiconductor chip CHP1, the semiconductor chip CHP3 and the semiconductor chip CHP2 is the X direction. Thus, the arrangement direction in plan view of the first upper-layer inductor UL1B and the second upper-layer inductor UL2B is parallel to the arrangement direction in plan view of the semiconductor chip CHP1, the semiconductor chip CHP3 and the semiconductor chip CHP2.

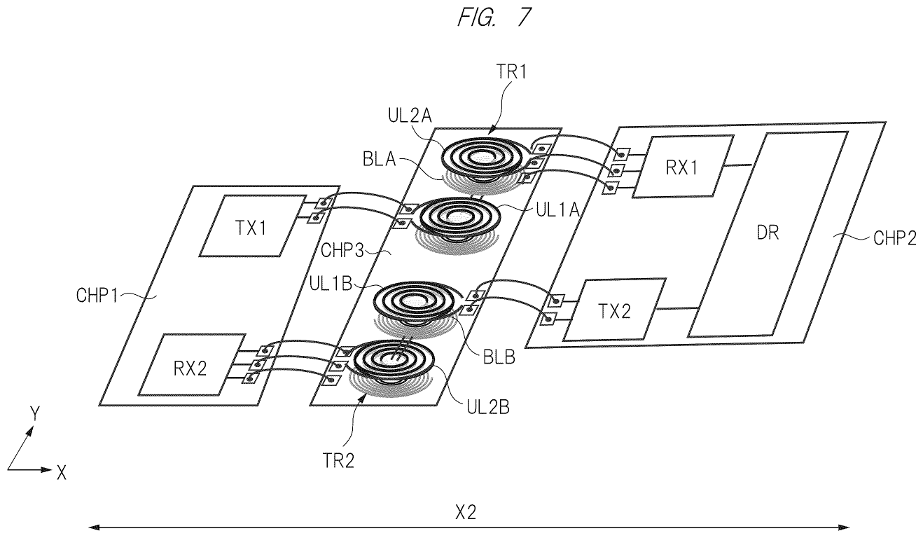

FIG. 7 is a diagram illustrating another exemplary layout configuration of transformers.

In FIG. 7, the semiconductor chip CHP3 is the “transformer chip”. The semiconductor chip CHP3 includes the transformer TR1 and the transformer TR2.

The transformer TR1 includes the lower-layer inductor BLA, the first upper-layer inductor UL1A, and the second upper-layer inductor UL2A.

The first upper-layer inductor UL1A and the second upper-layer inductor UL2A are arranged above the lower-layer inductor BLA. The lower-layer inductor BLA and the first upper-layer inductor UL1A are magnetically coupled. The lower-layer inductor BLA and the second upper-layer inductor UL2A are also magnetically coupled. As illustrated in FIG. 7, the first upper-layer inductor UL1A and the second upper-layer inductor UL2A are arranged side by side in the Y direction while being spaced apart from each other.

The arrangement direction in plan view of the semiconductor chip CHP1, the semiconductor chip CHP3 and the semiconductor chip CHP2 is the X direction. Thus, the arrangement direction in plan view of the first upper-layer inductor UL1A and the second upper-layer inductor UL2A crosses the arrangement direction in plan view of the semiconductor chip CHP1, the semiconductor chip CHP3 and the semiconductor chip CHP2.

The transformer TR2 includes the lower-layer inductor BLB, the first upper-layer inductor UL1B, and the second upper-layer inductor UL2B.

The first upper-layer inductor UL1B and the second upper-layer inductor UL2B are arranged above the lower-layer inductor BLB. The lower-layer inductor BLB and the first upper-layer inductor UL1B are magnetically coupled. The lower-layer inductor BLB and the second upper-layer inductor UL2B are also magnetically coupled. As illustrated in FIG. 7, the first upper-layer inductor UL1B and the second upper-layer inductor UL2B are arranged side by side in the Y direction while being spaced apart from each other.

The arrangement direction in plan view of the semiconductor chip CHP1, the semiconductor chip CHP3 and the semiconductor chip CHP2 is the X direction. Thus, the arrangement direction in plan view of the first upper-layer inductor UL1B and the second upper-layer inductor UL2B crosses the arrangement direction in plan view of the semiconductor chip CHP1, the semiconductor chip CHP3 and the semiconductor chip CHP2.

For example, if the layout configuration of transformers illustrated in FIG. 6 is adopted, an arrangement-direction (X-direction) length of the semiconductor chip CHP1, the semiconductor chip CHP3 and the semiconductor chip CHP2 is “X1”. To the contrary, if the layout configuration of transformers illustrated in FIG. 7 is adopted, an arrangement-direction (X-direction) length of the semiconductor chip CHP1, the semiconductor chip CHP3 and the semiconductor chip CHP2 is “X2”. The length “X2” is smaller than the length “X1”. Thus, the semiconductor device adopting the layout configuration of transformers illustrated in FIG. 7 can be further downsized than the semiconductor device adopting the layout configuration of transformers illustrated in FIG. 6.

### Mounting Configuration of Semiconductor Device

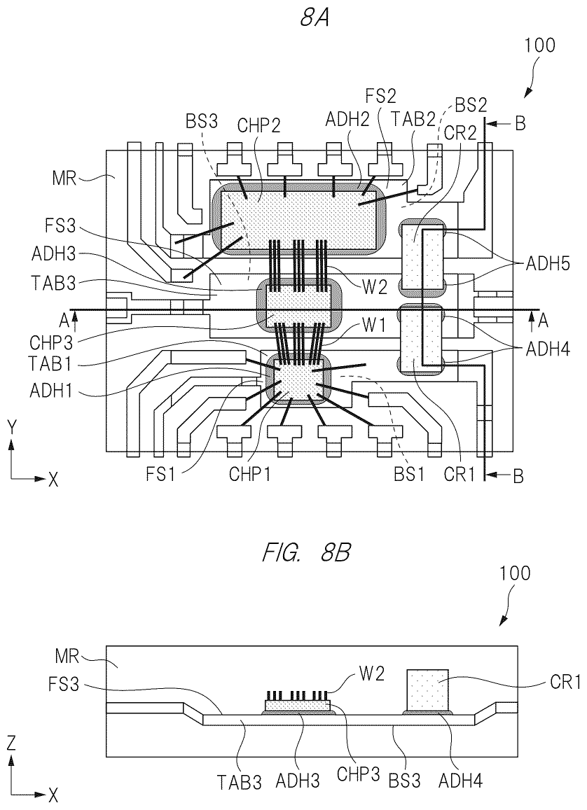

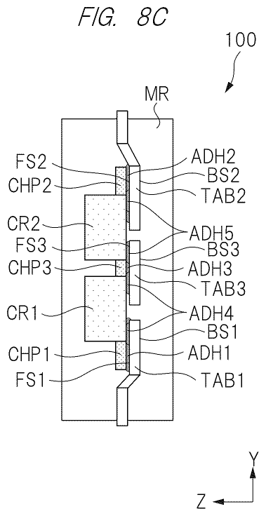

FIGS. 8A, 8B, and 8C are diagrams illustrating a mounting configuration of a semiconductor device 100 according to the first embodiment. FIG. 8A is a top view illustrating the mounting configuration of the semiconductor device 100. FIG. 8B is a cross-sectional view taken along the line A-A of FIG. 8A. FIG. 8C is a cross-sectional view taken along the line B-B of FIG. 8A.

As illustrated in FIGS. 8A to 8C, the semiconductor device 100 includes a sealing body MR, the chip mounting portion TAB1, the chip mounting portion TAB2, the chip mounting portion TAB3, an adhesive material ADH1, an adhesive material ADH2, an adhesive material ADH3, an adhesive material ADH4, an adhesive material ADH5, the semiconductor chip CHP1, the semiconductor chip CHP2, the semiconductor chip CHP3, a chip resistor CR1, and a chip resistor CR2. Note that the semiconductor device 100 further includes a plurality of leads and a plurality of bonding wires as other components. The plurality of bonding wires include a bonding wire W1 for electrically connecting the semiconductor chip CHP1 and the semiconductor chip CHP3 to each other and a bonding wire W2 for electrically connecting the semiconductor chip CHP2 and the semiconductor chip CHP3 to each other.

Each of FIGS. 8A to 8C illustrates a transparent inside diagram of the sealing body MR.

The chip mounting portion TAB1, the chip mounting portion TAB3, and the chip mounting portion TAB2 are arranged side by side in the Y direction in this order. That is, in the Y direction, the chip mounting portion TAB3 is arranged between the chip mounting portion TAB1 and the chip mounting portion TAB2.

The semiconductor chip CHP1 is arranged on the chip mounting portion TAB1 via the adhesive material ADH1. The adhesive material ADH1 is made of, for example, silver paste or solder.

The semiconductor chip CHP2 is arranged on the chip mounting portion TAB2 via the adhesive material ADH2. The adhesive material ADH2 is made of, for example, silver paste or solder.

The semiconductor chip CHP3 is arranged on the chip mounting portion TAB3 via the adhesive material ADH3. The adhesive material AHD3 is made of, for example, silver paste or solder.

For example, a plane size of the semiconductor chip CHP3 is larger than a plane size of the semiconductor chip CHP1 and is smaller than a plane size of the semiconductor chip CHP2. That is, in the plane size, the semiconductor chip CHP1 out of the semiconductor chip CHP1, the semiconductor chip CHP2, and the semiconductor chip CHP3 is the smallest while the semiconductor chip CHP2 thereof is the largest.

The semiconductor chip CHP1 is electrically connected to the lead via the bonding wire. The semiconductor chip CHP1 is electrically connected to the semiconductor chip CHP3 via the bonding wire.

The semiconductor chip CHP2 is electrically connected to the lead via the bonding wire. The semiconductor chip CHP2 is electrically connected to the semiconductor chip CHP3 via the bonding wire.

The semiconductor chip CHP3 is electrically connected to the semiconductor chip CHP1 via the bonding wire. The semiconductor chip CHP3 is electrically connected to the semiconductor chip CHP2 via the bonding wire.

The chip mounting portion TAB1 has a first front surface FS1 and a first back surface BS1. The first front surface FS1 is a surface on which the semiconductor chip CHP1 is arranged. The first back surface BS1 is an opposite surface to the first front surface FS1.

The chip mounting portion TAB2 has a second front surface FS2 and a second back surface BS2. The second front surface FS2 is a surface on which the semiconductor chip CHP2 is arranged. The second back surface BS2 is an opposite surface to the second front surface FS2.

The chip mounting portion TAB3 has a third front surface FS3 and a third back surface BS3. The third front surface FS3 is a surface on which the semiconductor chip CHP3 is arranged. The third back surface BS3 is an opposite surface to the third front surface FS3.

The chip resistor CR1 is arranged so as to straddle the first front surface FS1 of the chip mounting portion TAB1 and the third front surface FS3 of the chip mounting portion TAB3. The chip resistor CR1 is arranged on the first front surface FS1 via the adhesive material ADH4, and is arranged on the third front surface FS3 via the adhesive material ADH4.

The chip resistor CR2 is arranged so as to straddle the second front surface FS2 of the chip mounting portion TAB2 and the third front surface FS3 of the chip mounting portion TAB3. The chip resistor CR2 is arranged on the second front surface FS2 via the adhesive material ADH5, and is arranged on the third front surface FS3 via the adhesive material ADH5.

In FIG. 8A, the arrangement direction in plan view of the semiconductor chip CHP1, the semiconductor chip CHP3 and the semiconductor chip CHP2 is the Y direction. The arrangement direction in plan view of the chip resistor CR1 and the chip resistor CR2 is also the Y direction. Thus, the arrangement direction in plan view of the semiconductor chip CHP1, the semiconductor chip CHP3 and the semiconductor chip CHP2 is parallel to the arrangement direction in plan view of the chip resistor CR1 and the chip resistor CR2.

As described above, when the arrangement direction in plan view of the semiconductor chip CHP1, the semiconductor chip CHP3 and the semiconductor chip CHP2 is equal to the arrangement direction in plan view of the chip resistor CR1 and the chip resistor CR2, voids are difficult to be caused in the resin material injected into a cavity in the molding step of forming the sealing body MR. That is, in the mounting configuration of the semiconductor device 100 according to the first embodiment, “void trap countermeasures” in the molding step is taken into consideration.

In the first embodiment, the chip resistor CR1 and the chip resistor CR2 are arranged on the same surface side (mounting surface, arrangement surface) as the surface on which the semiconductor chip CHP1, the semiconductor chip CHP2, and the semiconductor chip CHP3 are mounted. Thus, the lead frame does not need to be inverted in order to arrange the chip resistor CR1 and the chip resistor CR2. Therefore, assembly easiness in the assembly steps (from a die bonding step to a wire bonding step) can be improved.

As illustrated in FIGS. 8B and 8C, an end of the lead is bent, for example, upward.

### Method of Manufacturing Semiconductor Device

Next, an exemplary method of manufacturing the semiconductor device according to the first embodiment will be described.

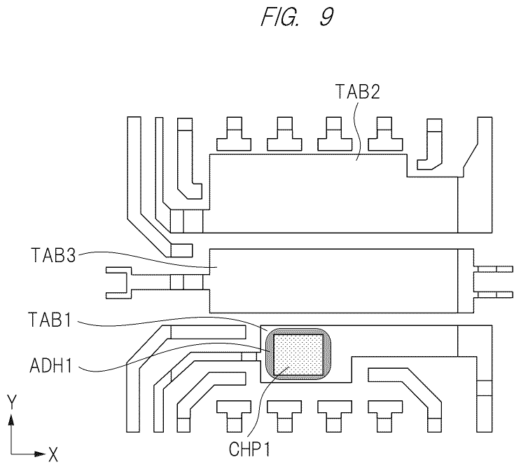

At first, as illustrated in FIG. 9, a lead frame including the chip mounting portion TAB1, the chip mounting portion TAB2, the chip mounting portion TAB3, and the plurality of leads is prepared. The semiconductor chip CHP1 is arranged on the chip mounting portion TAB1 via the adhesive material ADH1.

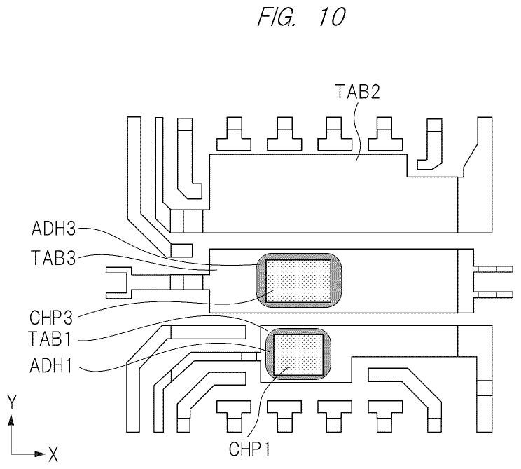

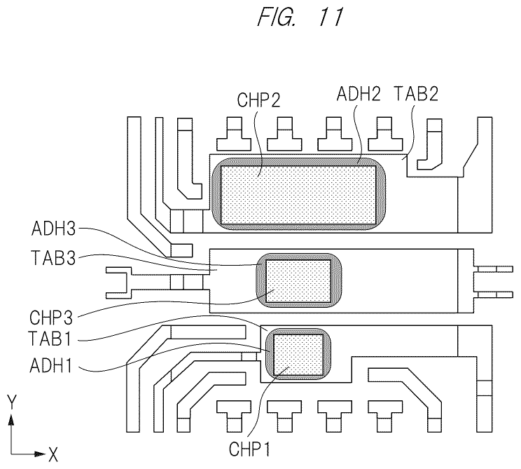

Next, as illustrated in FIG. 10, the semiconductor chip CHP3 is then arranged on the chip mounting portion TAB3 via the adhesive material ADH3. Thereafter, as illustrated in FIG. 11, the semiconductor chip CHP2 is arranged on the chip mounting portion TAB2 via the adhesive material ADH2. Subsequently, as illustrated in FIG. 12, the chip resistor CR1 is arranged so as to straddle the chip mounting portion TAB1 and the chip mounting portion TAB3 via the adhesive material ADH4, and the chip resistor CR2 is arranged so as to straddle the chip mounting portion TAB2 and the chip mounting portion TAB3 via the adhesive material ADH5. Thereafter, a thermal treatment is performed to the lead frame, thereby hardening the adhesive material ADH1, the adhesive material ADH2, the adhesive material ADH3, the adhesive material ADH4, and the adhesive material ADH5.

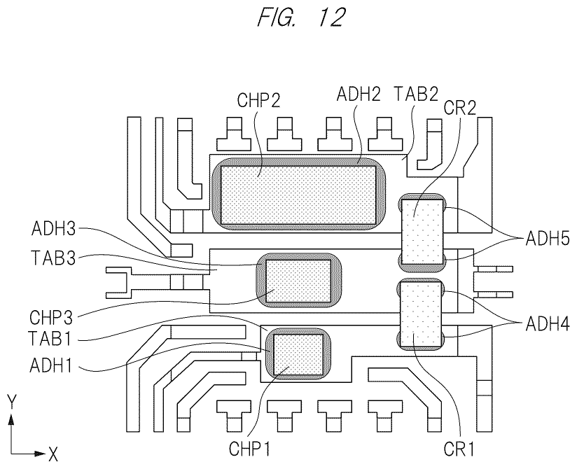

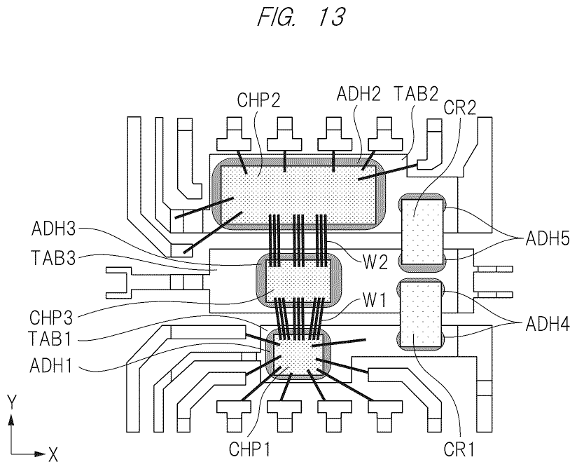

Then, as illustrated in FIG. 13, the wire bonding step is performed.

Specifically, the semiconductor chip CHP1 and the lead are electrically connected to each other via the bonding wire. The semiconductor chip CHP1 and the semiconductor chip CHP3 are electrically connected to each other via the bonding wire W1. The semiconductor chip CHP2 and the lead are electrically connected to each other via the bonding wire. The semiconductor chip CHP2 and the semiconductor chip CHP3 are electrically connected to each other via the bonding wire W2.

More specifically, the first upper-layer inductor UL1 provided on the semiconductor chip CHP3 is electrically connected to the semiconductor chip CHP1 via the bonding wire W1. The second upper-layer inductor UL2 provided on the semiconductor chip CHP3 is electrically connected to the semiconductor chip CHP2 via the bonding wire W2.

Thereafter, as illustrated in FIG. 14, the molding step is performed. Specifically, at least the semiconductor chip CHP1, the semiconductor chip CHP2, the semiconductor chip CHP3, the chip resistor CR1, and the chip resistor CR2 are sealed with the resin material, thereby forming the sealing body MR.

Subsequently, “burrs” formed on the sealing body MR are removed, and then, a plating film is formed on a part of the lead exposed from the sealing body MR. Then, a mark is formed on the surface of the sealing body MR. Thereafter, the lead exposed from the sealing body MR is shaped. Then, the lead frame is cut. Thereby, the semiconductor device according to the first embodiment can be manufactured.

Each of the adhesive material ADH1, the adhesive material ADH2, the adhesive material ADH3, the adhesive material ADH4, and the adhesive material ADH5 is made of, for example, silver paste or solder.

In the exemplary method of manufacturing the semiconductor device, baking (thermal treatment) is performed after the step of arranging the semiconductor chip CHP1 on the chip mounting portion TAB1 via the adhesive material ADH1, the step of arranging the semiconductor chip CHP3 on the chip mounting portion TAB3 via the adhesive material ADH3, the step of arranging the semiconductor chip CHP2 on the chip mounting portion TAB2 via the adhesive material ADH2, the step of arranging the chip resistor CR1 so as to straddle the chip mounting portion TAB1 and the chip mounting portion TAB3 via the adhesive material ADH4, and the step of arranging the chip resistor CR2 so as to straddle the chip mounting portion TAB2 and the chip mounting portion TAB3 via the adhesive material ADH5, thereby collectively hardening the adhesive material ADH1, the adhesive material ADH2, the adhesive material ADH3, the adhesive material ADH4, and the adhesive material ADH5. Thereby, the number of steps and the time of the steps can be reduced.

For example, when the silver paste is used for the adhesive material ADH1, the adhesive material ADH2, the adhesive material ADH3, the adhesive material ADH4, and the adhesive material ADH5, the collective baking causes a risk of drying of the initially applied silver paste before the collective baking. The drying increases a possibility of occurrence of the voids in the silver paste. Consequently, there is a risk of decrease in heat radiation performance. Thus, the method of manufacturing the semiconductor device adopts the following devisal.

That is, in attention to the semiconductor chip CHP1, the semiconductor chip CHP2, and the semiconductor chip CHP3, the plane size of the semiconductor chip CHP1 is the smallest while the plane size of the semiconductor chip CHP2 is the largest among. That is, an amount of generated heat in the semiconductor chip CHP1 is the smallest while an amount of generated heat in the semiconductor chip CHP2 is the largest. Therefore, it is important to secure the heat radiation performance in the adhesive material ADH2 adhesively bonding the chip mounting portion TAB2 and the semiconductor chip CHP2 with the largest amount of generated heat. In the exemplary method of manufacturing the semiconductor device, for example, as illustrated in FIGS. 9 to 11, the step of arranging the semiconductor chip CHP2 on the chip mounting portion TAB2 via the adhesive material ADH2 is performed after the step of arranging the semiconductor chip CHP1 on the chip mounting portion TAB1 via the adhesive material ADH1 and the step of arranging the semiconductor chip CHP3 on the chip mounting portion TAB3 via the adhesive material ADH3. Thereby, time taken from the application of the adhesive material ADH2 to the collective baking can be reduced, and therefore, the drying of the adhesive material ADH2 adhesively bonding the chip mounting portion TAB2 and the semiconductor chip CHP2 with the large amount of generated heat can be suppressed. Thus, in the adhesive material ADH2 which is most in need of the secure of the heat radiation performance, a decrease in the heat radiation performance due to the drying can be suppressed.

Next, another exemplary method of manufacturing the semiconductor device will be described.

The steps illustrated in FIGS. 9 to 11 are the same as those of the above exemplary method of manufacturing the semiconductor device.

Thereafter, a thermal treatment (first baking) is performed to the lead frame, thereby hardening the adhesive material ADH1, the adhesive material ADH2, and the adhesive material ADH3.

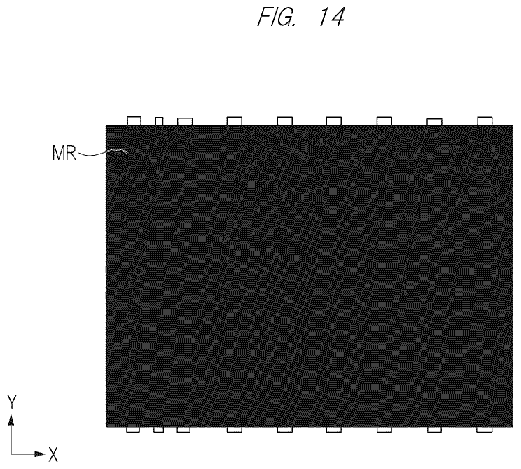

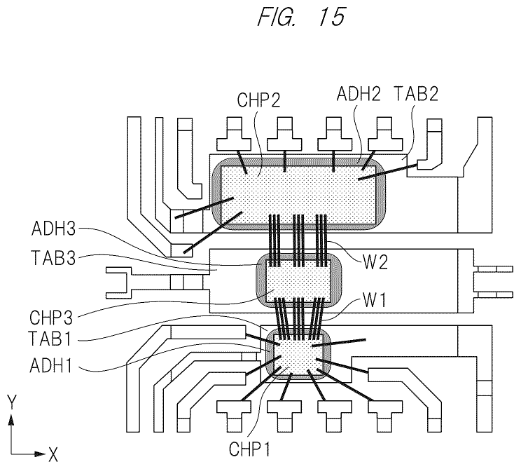

Then, as illustrated in FIG. 15, the wire bonding step is performed. Specifically, the semiconductor chip CHP1 and the lead are electrically connected to each other via the bonding wire. The semiconductor chip CHP1 and the semiconductor chip CHP3 are electrically connected to each other via the bonding wire W1. The semiconductor chip CHP2 and the lead are electrically connected to each other via the bonding wire. The semiconductor chip CHP2 and the semiconductor chip CHP3 are electrically connected to each other via the bonding wire W2.

More specifically, the first upper-layer inductor UL1 provided on the semiconductor chip CHP3 is electrically connected to the semiconductor chip CHP1 via the bonding wire W1. The second upper-layer inductor UL2 provided on the semiconductor chip CHP3 is electrically connected to the semiconductor chip CHP2 via the bonding wire W2.

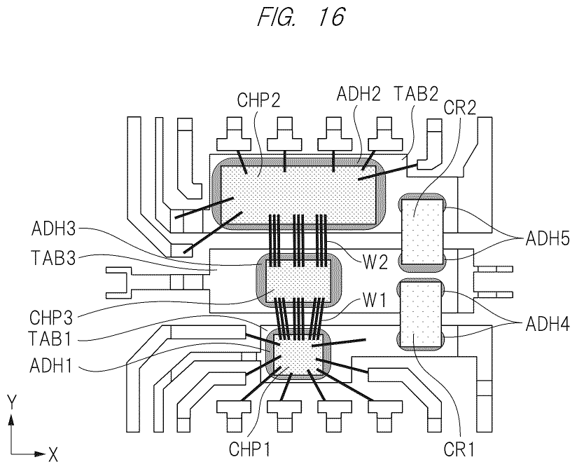

Then, as illustrated in FIG. 16, the chip resistor CR1 is arranged so as to straddle the chip mounting portion TAB1 and the chip mounting portion TAB3 via the adhesive material ADH4, and the chip resistor CR2 is arranged so as to straddle the chip mounting portion TAB2 and the chip mounting portion TAB3 via the adhesive material ADH5. Thereafter, a thermal treatment (second baking) is performed to the lead frame, thereby hardening the adhesive material ADH4 and the adhesive material ADH5.

The subsequent steps are the same as those of the above exemplary method of manufacturing the semiconductor device.

The wire bonding step is performed while the leads are clamped by a lead pressing jig. The clamping of the leads by the lead pressing jig possibly peels the chip resistor CR1 adhesively bonded by the adhesive material ADH4 so as to straddle the chip mounting portion TAB1 and the chip mounting portion TAB3 and the chip resistor CR2 adhesively bonded by the adhesive material ADH5 so as to straddle the chip mounting portion TAB2 and the chip mounting portion TAB3. That is, the wire bonding step performed after the chip resistor CR1 and the chip resistor CR2 are mounted on the lead frame causes a risk of decrease in the mounting reliability of the chip resistors CR1 and CR2.

In this regard, in another exemplary method of manufacturing the semiconductor device, as illustrated in FIGS. 15 and 16, the chip resistor CR1 and the chip resistor CR2 are mounted on the lead frame after the wire bonding step is performed. Thereby, another exemplary method of manufacturing the semiconductor device can suppress the peeling of the chip resistor CR1 and the chip resistor CR2 from the lead frame due to the wire bonding step. That is, in another exemplary method of manufacturing the semiconductor device, the mounting reliability of the resistors CR1 and CR2 can be improved.

### Devisal for Molding Step

The molding step is a step of forming the sealing body MR by sealing, with the resin material, at least the semiconductor chip CHP1, the semiconductor chip CHP2, the semiconductor chip CHP3, the chip resistor CR1, and the chip resistor CR2.

The molding step adopts, for example, a “through-gate molding system”.

FIG. 17 is a diagram schematically illustrating the “through-gate molding system”.

In FIG. 17, the resin material is injected in an arrow direction. In the first embodiment, the chip resistor CR1 and the chip resistor CR2 are arranged. A height of the chip resistor CR1 and a height of the chip resistor CR2 are larger than, for example, a height of the semiconductor chip CHP1, a height of the semiconductor chip CHP2, and a height of the semiconductor chip CHP3. Thus, the “through-gate molding system” illustrated in FIG. 17 has a risk of failure in filling of the resin material due to the chip resistors CR1 and CR2.

Thus, in the first embodiment, a devisal is made for the molding step. The molding step in the first embodiment with the devisal will be described below.

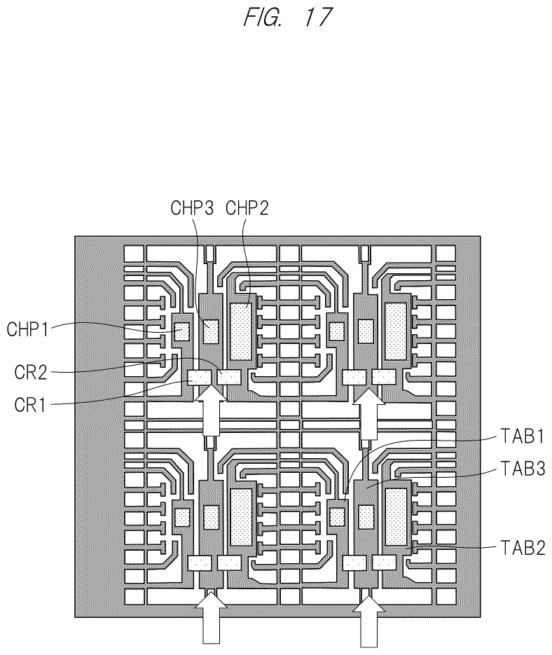

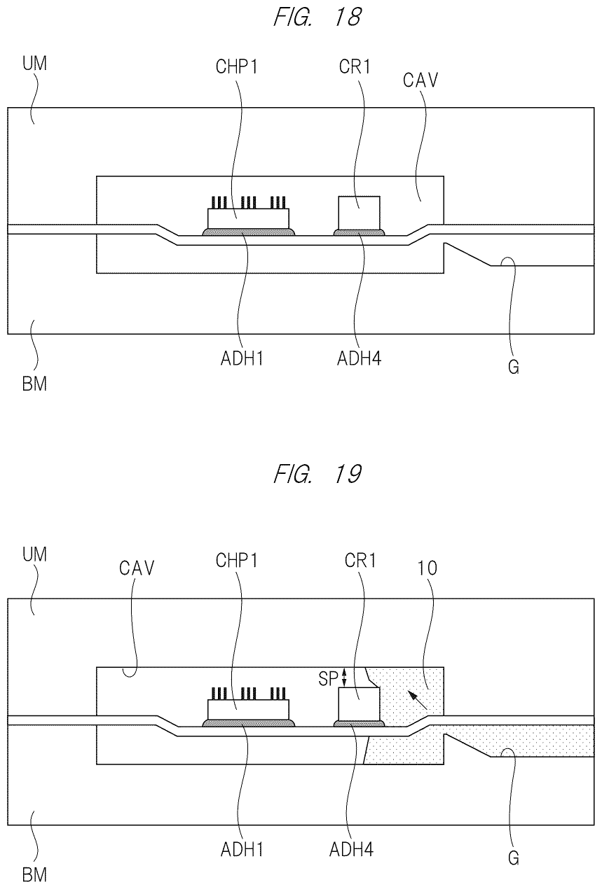

At first, as illustrated in FIG. 18, the lead frame is sandwiched between an upper mold UM and a lower mold BM while forming a cavity CAV such that the semiconductor chip CHP1, the semiconductor chip CHP2, the semiconductor chip CHP3, the chip resistor CR1, and the chip resistor CR2 are arranged in the cavity CAV. Since FIG. 18 is the cross-sectional view, the semiconductor chip CHP2, the semiconductor chip CHP3, and the chip resistor CR2 are not illustrated therein.

Thereafter, as illustrated in FIG. 19, the resin material 10 is injected from a gate G into the cavity CAV. Since the chip resistor CR1 is high, a space SP between the upper face of the chip resistor CR1 and the cavity CAV is the narrowest. Thus, in the first embodiment, in order to suppress the failure in the filling of the resin material 10 due to the narrowest space SP, the gate G is formed in the lower mold BM such that the resin material 10 is injected toward the narrowest space SP in the cavity CAV. Thereby, according to the first embodiment, the resin material 10 is also sufficiently injected into the narrowest space SP, and therefore, the failure of the filling of the resin material 10 can be suppressed.

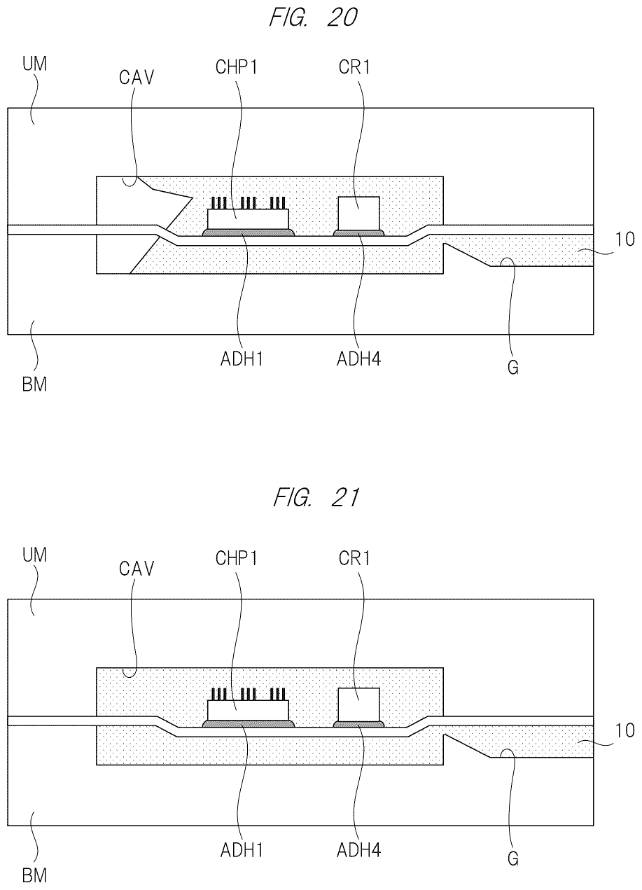

That is, as illustrated in FIGS. 20 and 21, since the cavity CAV can be filled with the resin material 10, the sealing body MR can be formed without the failure in the filling.

### Second Embodiment

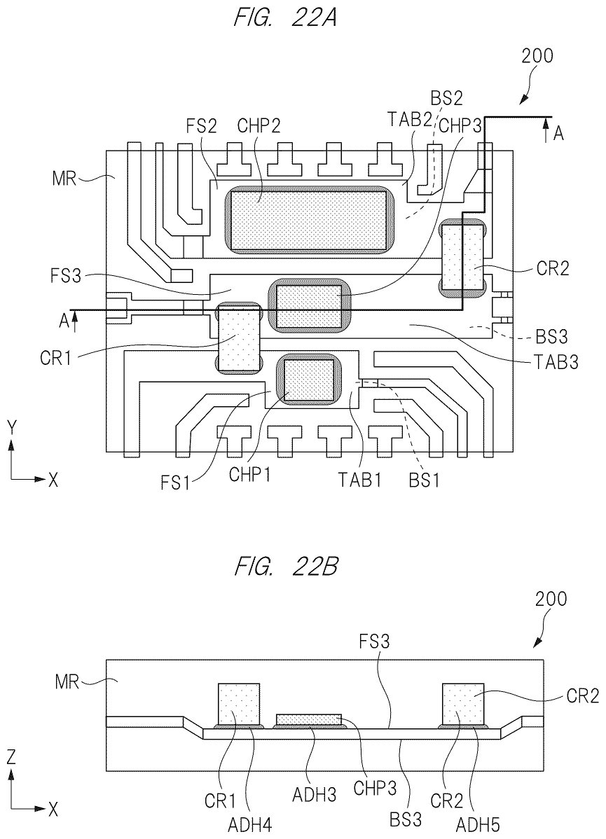

FIGS. 22A and 22B are diagrams illustrating a mounting configuration of a semiconductor device 200 according to a second embodiment.

FIG. 22A is a top view illustrating the mounting configuration of the semiconductor device 200. FIG. 22B is a cross-sectional view taken along the line A-A of FIG. 22A. Note that the bonding wires are not illustrated in FIGS. 22A and 22B.

The chip mounting portion TAB1 has the first front surface FS1 and the first back surface BS1. The first front surface FS1 is a surface on which the semiconductor chip CHP1 is arranged. The first back surface BS1 is an opposite surface to the first front surface FS1.

The chip mounting portion TAB2 has the second front surface FS2 and the second back surface BS2. The second front surface FS2 is a surface on which the semiconductor chip CHP2 is arranged. The second back surface BS2 is an opposite surface to the second front surface FS2.

The chip mounting portion TAB3 has the third front surface FS3 and the third back surface BS3. The third front surface FS3 is a surface on which the semiconductor chip CHP3 is arranged. The third back surface BS3 is an opposite surface to the third front surface FS3.

The chip resistor CR1 is arranged so as to straddle the first front surface FS1 of the chip mounting portion TAB1 and the third front surface FS3 of the chip mounting portion TAB3. The chip resistor CR2 is arranged so as to straddle the second front surface FS2 of the chip mounting portion TAB2 and the third front surface FS3 of the chip mounting portion TAB3.

In FIG. 22A, the arrangement direction in plan view of the semiconductor chip CHP1, the semiconductor chip CHP3 and the semiconductor chip CHP2 is the Y direction. The arrangement direction in plan view of the chip resistor CR1 and the chip resistor CR2 is a direction crossing the Y direction. Thus, the arrangement direction in plan view of the semiconductor chip CHP1, the semiconductor chip CHP3 and the semiconductor chip CHP2 crosses the arrangement direction in plan view of the chip resistor CR1 and the chip resistor CR2.

In the semiconductor device 200 according to the second embodiment configured as described above, the chip resistor CR1 and the chip resistor CR2 are arranged along a diagonal line of the chip mounting portion TAB3. Thus, the potential of the chip mounting portion TAB3 is easily stabilized. Consequently, the potential of the lower-layer inductor, which is capacitively coupled with the chip mounting portion TAB3, is also easily stabilized.

### Third Embodiment

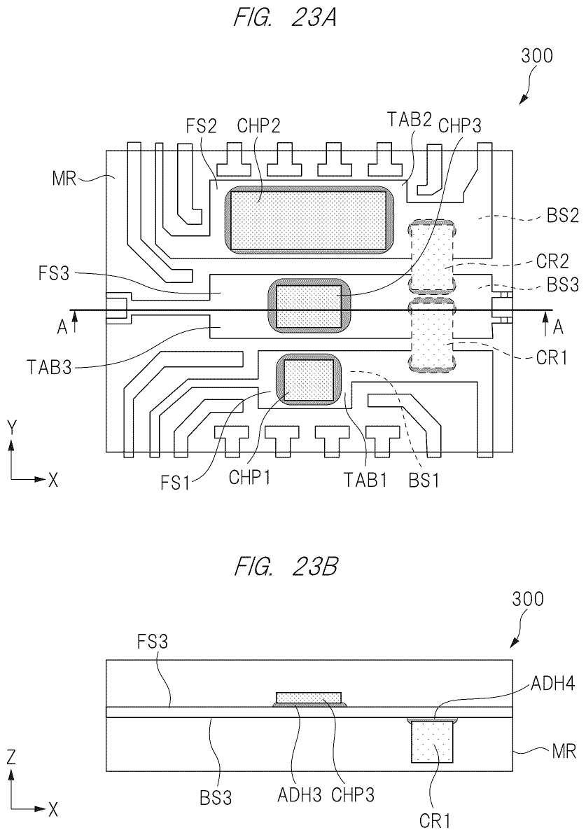

FIGS. 23A and 23B are diagrams illustrating a mounting configuration of a semiconductor device 300 according to a third embodiment.

FIG. 23A is a top view illustrating the mounting configuration of the semiconductor device 300. FIG. 23B is a cross-sectional view taken along the line A-A of FIG. 23A. Note that the bonding wires are not illustrated in FIGS. 23A and 23B.

The chip mounting portion TAB1 has the first front surface FS1 and the first back surface BS1. The first front surface FS1 is a surface on which the semiconductor chip CHP1 is arranged. The first back surface BS1 is an opposite surface to the first front surface FS1.

The chip mounting portion TAB2 has the second front surface FS2 and the second back surface BS2. The second front surface FS2 is a surface on which the semiconductor chip CHP2 is arranged. The second back surface BS2 is an opposite surface to the second front surface FS2.

The chip mounting portion TAB3 has the third front surface FS3 and the third back surface BS3. The third front surface FS3 is a surface on which the semiconductor chip CHP3 is arranged. The third back surface BS3 is an opposite surface to the third front surface FS3.

The chip resistor CR1 is arranged so as to straddle the first back surface BS1 of the chip mounting portion TAB1 and the third back surface BS3 of the chip mounting portion TAB3. The chip resistor CR2 is arranged so as to straddle the second back surface BS2 of the chip mounting portion TAB2 and the third back surface BS3 of the chip mounting portion TAB3.

In FIG. 23A, the arrangement direction in plan view of the semiconductor chip CHP1, the semiconductor chip CHP3 and the semiconductor chip CHP2 is the Y direction. The arrangement direction in plan view of the chip resistor CR1 and the chip resistor CR2 is also the Y direction. Thus, the arrangement direction in plan view of the semiconductor chip CHP1, the semiconductor chip CHP3 and the semiconductor chip CHP2 is parallel to the arrangement direction in plan view of the chip resistor CR1 and the chip resistor CR2.

According to the third embodiment, the chip resistor CR1 is not arranged on the first front surface FS1 and the third front surface FS3. The chip resistor CR2 is not arranged on the second front surface FS2 and the third front surface FS3. Thereby, the degree of freedom of the layout of the semiconductor chip CHP1, the semiconductor chip CHP2, and the semiconductor chip CHP3 can be improved. Further, each planar size of the chip mounting portion TAB1, the chip mounting portion TAB2, and the chip mounting portion TAB3 can be downsized.

### Fourth Embodiment

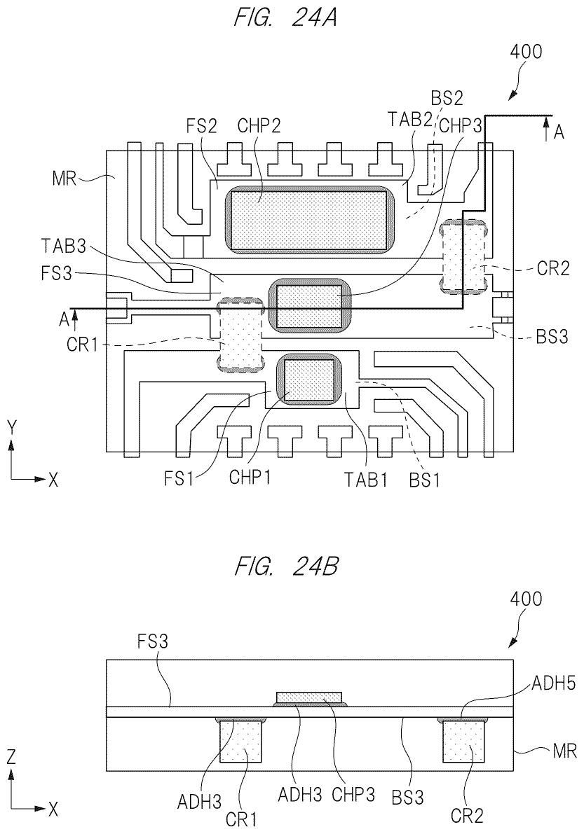

FIGS. 24A and 24B are diagrams illustrating a mounting configuration of a semiconductor device 400 according to a fourth embodiment.

FIG. 24A is a top view illustrating the mounting configuration of the semiconductor device 400. FIG. 24B is a cross-sectional view taken along the line A-A of FIG. 24A. Note that the bonding wires are not illustrated in FIGS. 24A and 24B.

The chip mounting portion TAB1 has the first front surface FS1 and the first back surface BS1. The first front surface FS1 is a surface on which the semiconductor chip CHP1 is arranged. The first back surface BS1 is an opposite surface to the first front surface FS1.

The chip mounting portion TAB2 has the second front surface FS2 and the second back surface BS2. The second front surface FS2 is a surface on which the semiconductor chip CHP2 is arranged. The second back surface BS2 is an opposite surface to the second front surface FS2.

The chip mounting portion TAB3 has the third front surface FS3 and the third back surface BS3. The third front surface FS3 is a surface on which the semiconductor chip CHP3 is arranged. The third back surface BS3 is an opposite surface to the third front surface FS3.

The chip resistor CR1 is arranged so as to straddle the first back surface BS1 of the chip mounting portion TAB1 and the third back surface BS3 of the chip mounting portion TAB3. The chip resistor CR2 is arranged so as to straddle the second back surface BS2 of the chip mounting portion TAB2 and the third back surface BS3 of the chip mounting portion TAB3.

In FIG. 24A, the arrangement direction in plan view of the semiconductor chip CHP1, the semiconductor chip CHP3 and the semiconductor chip CHP2 is the Y direction. The arrangement direction in plan view of the chip resistor CR1 and the chip resistor CR2 is a direction crossing the Y direction. Thus, the arrangement direction in plan view of the semiconductor chip CHP1, the semiconductor chip CHP3 and the semiconductor chip CHP2 crosses the arrangement direction in plan view of the chip resistor CR1 and the chip resistor CR2.

In the semiconductor device 400 according to the fourth embodiment configured as described above, the chip resistor CR1 and the chip resistor CR2 are arranged along a diagonal line of the chip mounting portion TAB3. Thus, the potential of the chip mounting portion TAB3 is easily stabilized. Consequently, the potential of the lower-layer inductor, which is capacitively coupled with the chip mounting portion TAB3, is also easily stabilized.

According to the fourth embodiment, the chip resistor CR1 is not arranged on the first front surface FS1 and the third front surface FS3. The chip resistor CR2 is not arranged on the second front surface FS2 and the third front surface FS3. Thereby, the degree of freedom of the layout of the semiconductor chip CHP1, the semiconductor chip CHP2, and the semiconductor chip CHP3 can be improved. Further, each planar size of the chip mounting portion TAB1, the chip mounting portion TAB2, and the chip mounting portion TAB3 can be downsized.

In the foregoing, the invention made by the inventors of the present application has been concretely described based on the embodiments. However, it is needless to say that the present invention is not limited to the foregoing embodiments, and various modifications can be made within the scope of the present invention.

For example, in the description of the embodiments, the “transformer communication” between inductors has been exemplified. However, the basic concept of the embodiments is not limited thereto, and is also applicable to “inter-electrode communication” of capacitors. In the capacitor case, instead of the lower-layer inductor BL, a lower electrode is arranged in the multi-layered wiring layer. Instead of the first upper-layer inductor UL1, a first upper electrode is arranged in the multi-layered wiring layer. Instead of the second upper-layer inductor UL2, a second upper electrode is arranged in the multi-layered wiring layer. Each of the lower electrode, the first upper electrode, and the second upper electrode is made of a plate-shaped wiring. The first upper electrode and the lower electrode can be capacitively coupled. The second upper electrode and the lower electrode can be capacitively coupled. The potential applied to the first upper electrode is equal to the potential applied to the first upper-layer inductor UL1. The potential applied to the second upper electrode is equal to the potential applied to the second upper-layer inductor UL2. The potential applied to the lower electrode is equal to the potential applied to the lower-layer inductor BL. The relationship between the first upper electrode and the other components is the same as the relationship between the first upper-layer inductor UL1 and the other components. The relationship between the second upper electrode and the other components is the same as the relationship between the second upper-layer inductor UL2 and the other components. The relationship between the lower electrode and the other components is the same as the relationship between the lower-layer inductor BL and the other components.

In the chapter <What is claimed is>, the term “lower-layer conductor portion” is used as a term for a concept including the lower-layer inductor and the lower electrode. The term “first upper-layer conductor portion” is used as a term for a concept including the first upper-layer inductor and the first upper electrode. The term “second upper-layer conductor portion” is used as a term for a concept including the second upper-layer inductor and the second upper electrode.

What is claimed is:

1. A semiconductor device comprising:
a first chip mounting portion to which a first potential is to be supplied;
a first semiconductor chip arranged on the first chip mounting portion;
a second chip mounting portion to which a second potential is to be supplied, the second potential being higher than the first potential;
a second semiconductor chip arranged on the second chip mounting portion;
a third chip mounting portion electrically connected to the first chip mounting portion via a first resistor element, and electrically connected to the second chip mounting portion via a second resistor element;
and an isolator chip arranged on the third chip mounting portion,
wherein the isolator chip includes:
a lower-layer conductor portion;
a first upper-layer conductor portion formed on the lower-layer conductor portion via an insulating layer and electrically connected to the first semiconductor chip; and
a second upper-layer conductor portion formed on the lower-layer conductor portion via the insulating layer, spaced apart from the first upper-layer conductor portion, and electrically connected to the second semiconductor chip.

2. The semiconductor device according to claim 1,
wherein the lower-layer conductor portion and the first upper-layer conductor portion are a component of a first transformer, and
wherein the lower-layer conductor portion and the second upper-layer conductor portion are a component of a second transformer.

3. The semiconductor device according to claim 1,
wherein the lower-layer conductor portion is a lower electrode,
wherein the first upper-layer conductor portion is a first upper electrode, and
wherein the second upper-layer conductor portion is a second upper electrode.

4. The semiconductor device according to claim 1,
wherein the first resistor element is a first chip resistor, and
wherein the second resistor element is a second chip resistor.

5. The semiconductor device according to claim 4,
wherein when an arrangement direction in plan view of the first semiconductor chip, the isolator chip and the second semiconductor chip is a first direction, and when an arrangement direction in plan view of the first chip resistor and the second chip resistor is a second direction, the first direction and the second direction are parallel to each other.

6. The semiconductor device according to claim 5,
wherein the first chip mounting portion has a first front surface on which the first semiconductor chip is arranged,
wherein the second chip mounting portion has a second front surface on which the second semiconductor chip is arranged,
wherein the third chip mounting portion has a third front surface on which the isolator chip is arranged,
wherein the first chip resistor is arranged so as to straddle the first front surface and the third front surface, and
wherein the second chip resistor is arranged so as to staddle the second front surface and the third front surface.

7. The semiconductor device according to claim 5,
wherein the first chip mounting portion has a first back surface on which the first semiconductor chip is not arranged,
wherein the second chip mounting portion has a second back surface on which the second semiconductor chip is not arranged,
wherein the third chip mounting portion has a third back surface on which the isolator chip is not arranged,
wherein the first chip resistor is arranged so as to straddle the first back surface and the third back surface, and
wherein the second chip resistor is arranged so as to straddle the second back surface and the third back surface.

8. The semiconductor device according to claim 4,
wherein when an arrangement direction in plan view of the first semiconductor chip, the isolator chip and the second semiconductor chip is a first direction, and when an arrangement direction in plan view of the first chip resistor and the second chip resistor is a third direction, the first direction and the third direction cross each other.

9. The semiconductor device according to claim 8,
wherein the first chip mounting portion has a first front surface on which the first semiconductor chip is arranged,
wherein the second chip mounting portion has a second front surface on which the second semiconductor chip is arranged,
wherein the third chip mounting portion has a third front surface on which the isolator chip is arranged,
wherein the first chip resistor is arranged so as to straddle the first front surface and the third front surface, and
wherein the second chip resistor is arranged so as to straddle the second front surface and the third front surface.

10. The semiconductor device according to claim 8,
wherein the first chip mounting portion has a first back surface on which the first semiconductor chip is not arranged,
wherein the second chip mounting portion has a second back surface on which the second semiconductor chip is not arranged,
wherein the third chip mounting portion has a third back surface on which the isolator chip is not arranged,
wherein the first chip resistor is arranged so as to straddle the first back surface and the third back surface, and
wherein the second chip resistor is arranged so as to straddle the second back surface and the third back surface.

11. The semiconductor device according to claim 4,
wherein a resistance value of the first chip resistor is in a range of 5 MΩ to 50 MΩ, and
wherein a resistance value of the second chip resistor is in a range of 5 MΩ to 50 MΩ.

12. The semiconductor device according to claim 1,
wherein a third potential applied to the third chip mounting portion is higher than the first potential, and is lower than the second potential.

13. The semiconductor device according to claim 1,
wherein when a distance between the lower-layer conductor portion and the first upper-layer conductor portion is a first distance, when a distance between the lower-layer conductor portion and the second upper-layer conductor portion is a second distance, and when a distance between the lower-layer conductor portion and the third chip mounting portion is a third distance, the third distance is smaller than each of the first distance and the second distance.

14. The semiconductor device according to claim 1,
wherein when an arrangement direction in plan view of the first semiconductor chip, the isolator chip and the second semiconductor chip is a first direction, and when an arrangement direction in plan view of the first upper-layer conductor portion and the second upper-layer conductor portion is a fourth direction, the first direction and the fourth direction cross each other.

15. A method of manufacturing a semiconductor device, comprising steps of:
(a) preparing a lead frame including a first chip mounting portion, a second chip mounting portion, and a third chip mounting portion;
(b) arranging a first semiconductor chip on the first chip mounting portion via a first adhesive material;
(c) arranging a second semiconductor chip on the second chip mounting portion via a second adhesive material;
(d) arranging an isolator chip on the third chip mounting portion via a third adhesive material;
(e) arranging a first chip resistor via a fourth adhesive material so as to straddle the first chip mounting portion and the third chip mounting portion;
(f) arranging a second chip resistor via a fifth adhesive material so as to straddle the second chip mounting portion and the third chip mounting portion; and
(g) after performing the step (b) to the step (e), preforming a thermal treatment to the lead frame, thereby hardening the first adhesive material, the second adhesive material, the third adhesive material, the fourth adhesive material and the fifth adhesive material.

16. The method of manufacturing the semiconductor device according to claim 15, comprising a step of:
(h) after performing the step (g), forming a sealing body that seals the first semiconductor chip, the second semiconductor chip, the isolator chip, the first chip resistor and the second chip resistor,
wherein the step (h) includes steps of:
(h1) sandwiching the lead frame between an upper mold and a lower mold while forming a cavity such that the first semiconductor chip, the second semiconductor chip, the isolator chip, the first chip resistor and the second chip resistor are arranged in the cavity; and
(h2) injecting a resin material from a gate into the cavity, and
wherein the gate is formed in one of the upper mold and the lower mold such that the resin material is injected toward a narrowest space in the cavity in which the first semiconductor chip, the second semiconductor chip, the isolator chip, the first chip resistor and the second chip resistor are arranged.

17. A method of manufacturing a semiconductor device, comprising steps of:
(a) preparing a lead frame including a first chip mounting portion, a second chip mounting portion, and a third chip mounting portion;
(b) arranging a first semiconductor chip on the first chip mounting portion via a first adhesive material;
(c) arranging a second semiconductor chip on the second chip mounting portion via a second adhesive material;
(d) arranging an isolator chip on the third chip mounting portion via a third adhesive material;
(e) after performing the step (b) to the step (d), performing a first thermal treatment to the lead frame, thereby hardening the first adhesive material, the second adhesive material and the third adhesive material;
(f) after performing the step (e), electrically connecting the first semiconductor chip and the third semiconductor chip to each other via a first bonding wire, and electrically connecting the second semiconductor chip and the third semiconductor chip to each other via a second bonding wire;
(g) after performing the step (f), arranging a first chip resistor via a fourth adhesive material so as to straddle the first chip mounting portion and the third chip mounting portion;
(h) arranging a second chip resistor via a fifth adhesive material so as to straddle the second chip mounting portion and the third chip mounting portion; and
(i) after performing the step (g) and the step (h), performing a second thermal treatment to the lead frame, thereby hardening the fourth adhesive material and the fifth adhesive material.

18. The method of manufacturing the semiconductor device according to claim 17, comprising a step of:
(j) after performing the step (i), forming a sealing body that seals the first semiconductor chip, the second semiconductor chip, the isolator chip, the first chip resistor and the second chip resistor,
wherein the (j) includes steps of:
(j1) sandwiching the lead frame between an upper mold and a lower mold while forming a cavity such that the first semiconductor chip, the second semiconductor chip, the isolator chip, the first chip resistor and the second chip resistor are arranged in the cavity; and
(j2) injecting a resin material from a gate into the cavity, and
wherein the gate is formed in one of the upper mold and the lower mold such that the resin material is injected toward a narrowest space in the cavity in which the first semiconductor chip, the second semiconductor chip, the isolator chip, the first chip resistor and the second chip resistor are arranged.
